(19) United States
(12) Patent Application Publication
(10) Pub. No.: US 2025/0308971 A1
(43) Pub. Date: Oct. 2, 2025

(54) SEMICONDUCTOR DIE SINGULATION USING DIE ATTACH FILM AND PLASMA DICING

(71) Applicant: TEXAS INSTRUMENTS INCORPORATED, Dallas, TX (US)

(72) Inventors: Rongwei Zhang, Plano, TX (US); Michael Todd Wyant, Dallas, TX (US); Yuntao Xu, Chengdu (CN)

(21) Appl. No.: 18/622,204

(22) Filed: Mar. 29, 2024

(51) Int. Cl. H01L 21/683; H01L 21/78; H01L 23/00; H01L 23/495

(52) U.S. Cl. CPC H01L 21/6836; H01L 21/78; H01L 23/49513; H01L 24/29; H01L 24/32; H01L 24/45; H01L 24/48; H01L 24/73; H01L 24/83; H01L 24/85; H01L 24/92; H01L 24/94; H01L 24/97; H01L 2221/68336; H01L 2224/27436; H01L 2224/2929; H01L 2224/2939; H01L 2224/32245; H01L 2224/45124; H01L 2224/45139; H01L 2224/45144; H01L 2224/45147; H01L 2224/45664; H01L 2224/48091; H01L 2224/48245; H01L 2224/73265; H01L 2224/83191; H01L 2224/83862; H01L 2224/85043; H01L 2224/85207; H01L 2224/92247; H01L 2224/94; H01L 2224/97; H01L 2924/0615; H01L 2924/062; H01L 2924/0635; H01L 2924/0665

(57) ABSTRACT

An example semiconductor device package includes: a semiconductor die having a backside surface mounted to a die pad of a leadframe using a die attach film that includes polymer particles, the leadframe having leads spaced from the die pad; wire bonds coupling bond pads on a device side surface of the semiconductor die that is opposite the backside surface to the leads of the leadframe; and mold compound covering the semiconductor die, the wire bonds, and portions of the leads of the leadframe, with additional portions of the leads of the leadframe exposed from the mold compound to form terminals; wherein the semiconductor die has vertical sides extending from the backside surface to the device side surface that have a scalloped pattern.

### TECHNICAL FIELD

This disclosure relates generally to semiconductor dies, and more particularly to a method of semiconductor die singulation to remove individual dies from a semiconductor wafer.

### BACKGROUND

Semiconductor dies are produced for use in electronic circuits using semiconductor wafer manufacturing facilities (“wafer fabs”) to form identical semiconductor dies on a device side surface of a semiconductor wafer. Example semiconductor wafer materials include silicon, germanium, gallium arsenide, gallium nitride, sapphire, silicon carbide and indium phosphide, with silicon being the most commonly used semiconductor wafer material. In some examples, epitaxy can be used to form a layer of semiconductor material over a carrier wafer, for example silicon germanium (SiGe) can be formed as an epitaxial layer for use in forming devices. The processes used in forming semiconductor dies in a wafer fab include, without limitation, doping semiconductor layers with impurities to form doped regions, thermal anneals, thermal oxidation, deposition of dielectrics and of conductors, sputtering, etching, photolithography, ion implantation, plasma vapor deposition, chemical vapor deposition, damascene metal deposition, plating, chemical mechanical polishing, and polyimide deposition. Layers of metal conductors in layers of dielectric material are connected vertically by conductive vias to form electrical connections between the conductors which can be arranged to couple devices formed in the semiconductor substrate. Using these processes, individual transistors, analog circuits of several transistors and passive devices, power transistors and power circuits, and integrated circuits having hundreds, thousands or tens of thousands of connected transistors and devices can be formed in the semiconductor dies.

Once the semiconductor dies are complete, the individual devices are removed from the semiconductor wafer by a process referred to as “singulation.” In die singulation, the semiconductor wafer is separated into individual semiconductor dies by “wafer dicing.” In one approach, a mechanical saw is used. A rotating saw blade moves along scribe lanes formed between the semiconductor dies and cuts through the semiconductor wafer in multiple passes. During wafer dicing the semiconductor wafer is supported by a removable film or tape, a backside or dicing tape, that supports the dies as the scribe lanes are cut through. The semiconductor dies can be square or rectangular, tens, hundreds or even thousands of the dies can be formed on a single semiconductor wafer. The scribe lanes are areas on the wafer that are parallel to one another in two directions, so that each semiconductor die has four vertical sides after the dicing, the vertical sides extend from a device side surface to a backside surface, so that an individual semiconductor die has six sides, and is a cube.

Another dicing approach is to use laser wafer dicing. In one example process, a stealth laser dicing process is used. In stealth laser dicing, a laser beam is focused at a depth inside the semiconductor wafer and traverses the scribe lanes, often in multiple passes. As the laser beam applies energy to the semiconductor wafer in the scribe lanes, polysilicon is formed along stress regions, forming stress induced dislocations in the crystal lattice within the semiconductor wafer. To complete the die singulation, a stretching process applies tension to the dicing tape in multiple directions simultaneously, and the individual semiconductor dies break apart along the scribe lanes when the stress induced dislocation regions, which are weaker than the surrounding crystal lattice material, are pulled on by the stretching tape. In another approach, a laser is used to mechanically cut into the wafer along the scribe lanes in an ablation process.

After the semiconductor wafer is diced into individual semiconductor dies, the individual semiconductor dies are mounted to a package substrate and a semiconductor device package is formed. In an example process, the individual semiconductor dies are mounted to a die pad with bond pads on the semiconductor dies facing away from the die pad. A die attach film can be used to attach the semiconductor die to the die pad. Electrical connections are formed between the semiconductor die and leads of the package substate, for example wire bonds can be formed to couple bond pads of the semiconductor die to the leads of the package substrate. After the electrical connections are formed, a package body can be formed using a mold compound. For example, a transfer molding process can be used to cover the semiconductor die, the electrical connections, and portions of the package substrate with the mold compound, while portions of leads are left exposed from the mold compound to form device terminals for the semiconductor device package.

Prior to dicing the wafer, die attach film may be applied to the semiconductor wafer. Examples include non-conductive die attach film, which provides a thermally conductive, but electrically insulating, connection between the backside of the semiconductor dies and the package substrate.

In both mechanical saw dicing and laser wafer dicing small splinters or small pieces of residue of the semiconductor wafer material can form during dicing. These splinters or other debris can end up in the die attach film that is applied to the backside of the semiconductor wafer. These small pieces of semiconductor material can create an unwanted conductive electrical path between the backside of the semiconductor die and a conductive die pad in a package substrate and are a source of current leakage in unwanted packaged semiconductor devices. In some examples, a field failure can result, requiring return and scrapping of the finished device, or a test failure can cause the device to be scrapped due to the current leakage.

The semiconductor dies are mounted on the die attach film, which is a polymer material with fillers. The fillers can include, in some examples of die attach film that are presently used with semiconductor dies, alumina or silica particles. When alumina or silica is used as a filler, additional current leakage paths have been observed due to ion migration of copper and silver ions from a metal die pad surface of a copper or silver plated leadframe package substrate onto the surface of the alumina or silica particles within the die attach film, creating a potential conductive current path through the die attach film from the backside surface of the semiconductor die to the conductive die pad surface, forming another source of current leakage.

In forming semiconductor dies with increasingly smaller die areas, such as 0.25 by 0.25 millimeters, or even less, such as 0.1 by 0.1 millimeters, issues with failed separation of die attach film in laser dicing have been also been observed. However, if a thinner die attach film is used to improve the likelihood of complete die separation, the mechanical support needed from the die attach film during wire bonding, where a hard capillary pushes a bond wire against a bond pad on the semiconductor die, may not be sufficient, and the semiconductor die may tilt during the wire bonding process, resulting in additional defects.

Improvements in wafer dicing and die separation, reduction in scrapped or defective devices, and reduction in current leakage in packaged semiconductor devices are needed.

### SUMMARY

In a described example, a method includes: mounting a backside of a semiconductor wafer having semiconductor dies on an opposite device side surface to a dicing die attach film having an adhesive, the dicing die attach film including a die attach film including polymer particles mounted on a wafer dicing tape; performing a plasma dicing process to etch through the semiconductor wafer from the device side surface to expose the die attach film; separating the semiconductor dies one from another to form singulated semiconductor dies on corresponding portions of the die attach film; removing the singulated semiconductor dies and the corresponding die attach film portions from the wafer dicing tape; using the die attach film portions, mounting the singulated semiconductor dies on die pad portions of a leadframe in a leadframe strip; forming wire bonds electrically coupling leads of the leadframe to bond pads on the semiconductor dies; covering the semiconductor dies and at least a portion of the leads in mold compound; and cutting the leadframe strip and the mold compound along saw streets to separate the semiconductor dies covered in mold compound and mounted to the leadframe, forming separate packaged semiconductor devices each including a semiconductor die.

In another described example, another method of forming a semiconductor device package includes: mounting a backside of a semiconductor wafer having semiconductor dies on an opposite device side surface to a dicing die attach film having an adhesive, the dicing die attach film including a die attach film including polymer particles having a diameter of between 5 and 10 microns mounted on a wafer dicing tape; performing a plasma dicing process to etch through the semiconductor wafer from the device side surface in scribe lanes between the semiconductor dies to expose the die attach film; separating the semiconductor dies one from another to form singulated semiconductor dies on corresponding portions of the die attach film by stretching the wafer dicing tape to tear the die attach film apart in the scribe lanes, forming the corresponding portions of the die attach film; removing the singulated semiconductor dies and the corresponding die attach film portions from the dicing tape; using the corresponding die attach film portions, mounting the singulated semiconductor dies on die pad portions of a leadframe in a leadframe strip; forming wire bonds electrically coupling leads of the leadframe to bond pads on the semiconductor dies; covering the semiconductor dies and at least a portion of the leads in mold compound; and cutting the leadframe strip and the mold compound along saw streets to separate the semiconductor dies covered in mold compound and mounted to the leadframe, forming separate packaged semiconductor devices each including a semiconductor die.

In another described example, a semiconductor device package includes: a semiconductor die having a backside surface mounted to a die pad of a leadframe using a die attach film that includes polymer particles, the leadframe having conductive lead portions spaced from the die pad; wire bonds coupling bond pads on a device side surface of the semiconductor die that is opposite the backside surface to the conductive lead portions of the leadframe; and mold compound covering the semiconductor die, the wire bonds, and portions of the conductive leads of the leadframe, with additional portions of the conductive leads of the leadframe exposed from the mold compound to form terminals.

### BRIEF DESCRIPTION OF THE DRAWINGS

FIGS. 1A-B illustrate, in projection views, a semiconductor wafer and a semiconductor die, respectively.

FIGS. 2A-2B illustrate, in a projection view from a top side and in a cross section, respectively, a semiconductor device package that can be used with an arrangement.

FIGS. 3A-3D illustrate, in a series of views, selected steps used in a plasma dicing process for dicing a semiconductor wafer.

FIGS. 4A-4F illustrate, in a series of cross-sectional views, steps of a plasma dicing process that can be used with the arrangements.

FIGS. 5A-5C, 5CC, and 5D-5I illustrate, in a series of cross-sectional views, selected major steps for forming a semiconductor device package of an arrangement.

FIG. 6 is a flow diagram illustrating steps of a method for forming an arrangement.

### DETAILED DESCRIPTION

Corresponding numerals and symbols in the different figures generally refer to corresponding parts, unless otherwise indicated. The figures are not necessarily drawn to scale.

The term “scribe lane” is used herein. A scribe lane is a portion of semiconductor wafer between semiconductor dies. Sometimes in related literature the term “scribe street” is used. Once processing is finished and the semiconductor devices are complete, the semiconductor devices are separated into individual semiconductor dies by severing the semiconductor wafer along the scribe lanes. The separated dies can then be removed and handled individually for further processing including packaging. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

Elements are described herein as “coupled.” As used herein, the term “coupled” includes elements that are directly connected, and elements that are electrically connected even with intervening elements or wires are also coupled.

The term “semiconductor die” is used herein. A semiconductor die can be a discrete semiconductor device such as a bipolar transistor, a few discrete devices such as a pair of power field effect transistor (“FET”) switches fabricated together on a single semiconductor die, or an integrated circuit with multiple semiconductor devices in a circuit such as the multiple capacitors in an A/D converter. The semiconductor die can include passive devices such as resistors, inductors, filters, or active devices such as transistors. The semiconductor die can be an integrated circuit with hundreds or thousands of transistors coupled to form a functional circuit, for example a microprocessor or memory semiconductor device. The semiconductor die can be a passive device such as a sensor, example sensors include photocells, transducers, and charge coupled devices (“CCDs”), or can be a micromechanical device, such as a digital micromirror device (“DMD”) or a micro-electro-mechanical system (“MEMS”) device.

The term “stress induced dislocation” is used herein. In stealth laser dicing, laser energy is focused at particular locations within a semiconductor wafer in scribe lanes between semiconductor dies. The laser energy melts a portion of the semiconductor material forming polysilicon regions. Because the polysilicon takes a larger area than the surrounding semiconductor crystal lattice, forming the polysilicon by laser energy induces stress and dislocates the semiconductor crystal lattice in the region affected by the laser energy, resulting in a stress induced dislocation in the semiconductor substrate. When the semiconductor substrate is then stressed using in an expansion process, the stress induced dislocations can be propagated to form openings that eventually extend through the semiconductor substrate, the openings are formed along the scribe lanes and thus form singulated rectangular semiconductor dies.

The term “plasma dicing” is used. In plasma dicing, a semiconductor wafer is diced using a plasma chamber and performing a plasma etch process. In plasma dicing, a mask is applied over the device side surface of a semiconductor wafer. The mask is patterned to expose the scribe lanes. An isotropic etch is formed using a gas in the plasma chamber in a first step of a Bosch cycle. During the Bosch cycle, an etch is performed to a certain depth, then a deposition of a protective material is performed in the plasma chamber, followed by another etch to remove the protective material from the bottom of the trench, and then an additional etch is performed to deepen the trench. By repeating the etch and deposition cycle multiple times, highly isotropic etches can be performed and the semiconductor wafer can be etched completely through in the scribe lanes.

The term “dicing die attach film” is used herein. In the arrangements, a dicing die attach film is a combination of a die attach film and a dicing tape, laminated together. By laminating these materials together prior to mounting them to a semiconductor wafer, certain steps in providing these materials on the backside of a semiconductor wafer are simplified, lowering assembly costs.

In the arrangements, in addition to the use of plasma dicing, which eliminates the semiconductor debris or semiconductor splinter pieces formed using either mechanical sawing and laser dicing, a die attach film containing polymer particles is used. Die attach films used conventionally in packaging can be difficult or impossible to etch in a plasma etch process. In contrast, the die attach film with polymer particles used in the arrangements is compatible with the plasma dicing etch, and can be partially or totally etched by the plasma etch, enabling complete die separation after plasma dicing, even for small die sizes. Further the die attach film uses polymer particles, eliminating the alumina or silica fillers used in prior approaches, and thus eliminating current leakage observed due to metal ion migration on the surface of alumina or silica filler particles. The polymer particles used in the arrangements also provide mechanical support for semiconductor dies mounted using the die attach film. After dicing the wafer into individual semiconductor dies, the dies are mounted to a package substrate and wire bonding is used. In one advantageous aspect of the arrangements, the polymer particles of the novel die attach film provide increased mechanical support (compared to silica or alumina filler of prior approach die attach film) for wire bonding operations. The arrangements are particularly advantageous for wire bonding processes that include bonding with copper and with palladium coated copper (“PCC”) bond wire, which are harder than silver bond wire or gold bond wire, and which therefore require more mechanical force during bonding than softer gold or silver bond wires often used previously. Use of increased mechanical force on the bond pads to form the ball bonds increases the possibility of die tilt during wire bonding.

In the arrangements, use of the polymer particle containing die attach film of the arrangements advantageously reduces or eliminates die tilt problems that are particularly significant in copper and PCC wire bonding. The arrangements include attaching the die attach film to a semiconductor wafer prior to the plasma dicing process, and then performing pick and place to place the singulated dies (including a portion of the polymer containing die attach film that is disposed on the backside surface of the singulated dies) onto a die pad of a package substrate. Wire bonding is performed with the polymer containing die attach film providing increased mechanical support (compared to prior approach die attach) to the dies. The semiconductor dies and wire bonds are then covered with mold compound to form packaged semiconductor devices.

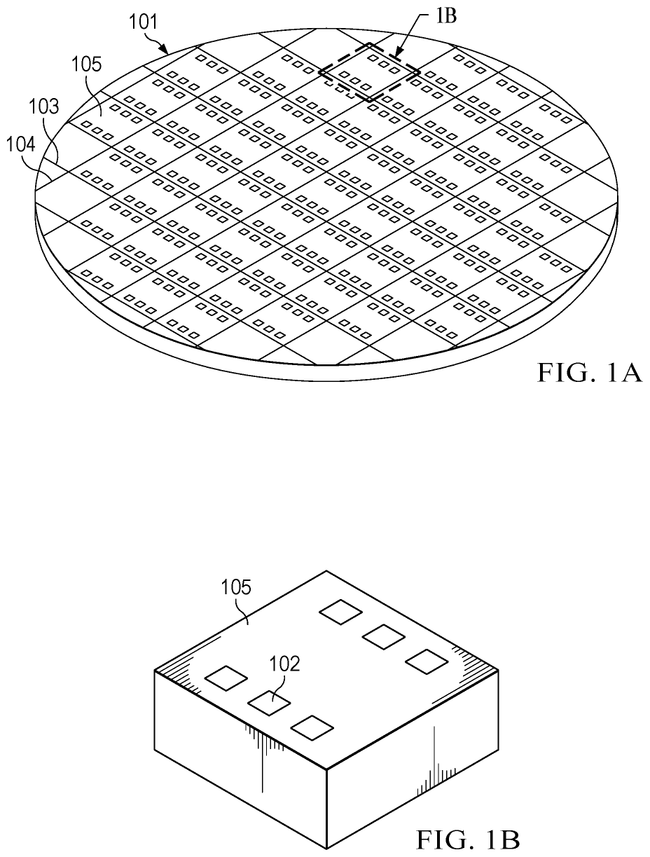

In FIG. 1A, a semiconductor wafer 101 is shown with an array of semiconductor dies 105 arranged in rows and columns. The semiconductor dies 105 can be formed using manufacturing processes in a semiconductor manufacturing facility, including ion implantation for carrier doping, anneals, oxidation, dielectric and conductor deposition, photolithography, pattern, etch, chemical mechanical polishing (“CMP”), electroplating, and other processes for making semiconductor devices. Devices (not shown for clarity) are formed on a device side surface of the semiconductor dies. Scribe lanes 103 and 104, which are perpendicular to one another and which run in parallel groups across the semiconductor wafer 101, separate the rows and columns of the completed semiconductor dies 105, and provide areas for dicing the wafer to separate the semiconductor dies 105 from one another.

FIG. 1B illustrates in a projection view a single semiconductor die 105 (from the semiconductor wafer 101 in FIG. 1A), with bond pads 102, which are conductive pads that are electrically coupled to devices (not shown for simplicity of illustration) formed in the semiconductor dies 105. The semiconductor dies 105 are separated from semiconductor wafer 101 by wafer dicing, or are singulated from one another, using the scribe lanes 103, 104 (see 103 and 104 in FIG. 1A). In the arrangements, plasma dicing is used to singulate the dies 105 from the semiconductor wafer 101.

In contrast to mechanical saw dicing or laser dicing, plasma dicing does not form chips or residue from the semiconductor wafer that can lodge in the die attach film and which can form conductive paths between the backside of the die and a die pad, these unwanted conductive paths can lead to current leakage in the packaged semiconductor devices. Further, plasma dicing does not vibrate the semiconductor dies or create heat affected stress zones within the semiconductor dies, as the semiconductor plasma etch process affects only the scribe lane material between the semiconductor dies. The minimum width of the scribe lanes needed for plasma dicing is substantially less than the minimum scribe lane widths required for either laser dicing or mechanical saw dicing, increasing the number of semiconductor dies that can be formed on a single semiconductor wafer, and increasing yields, which lowers unit costs. Use of the arrangements advantageously provides a die attach film that is compatible with plasma dicing, in contrast to prior approach die attach films.

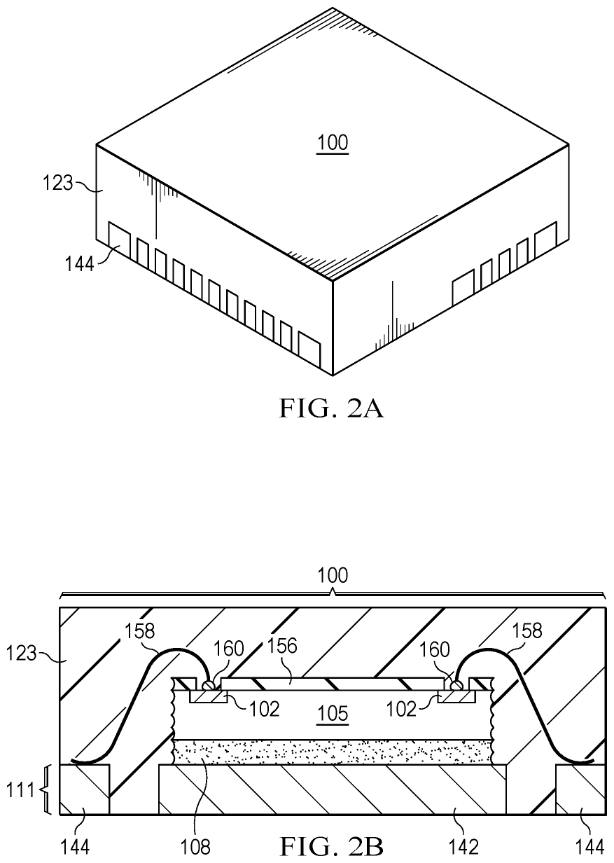

FIGS. 2A-2B illustrate, in a projection view and a cross-sectional view, respectively, a quad flat no-lead (“QFN”) package that is useful with the arrangements.

In FIG. 2A, a top side projection view illustrates a semiconductor device package 100 that is a QFN package. The semiconductor device package 100 has terminals 144 that are arranged for surface mounting to a circuit board or module using surface mount technology (“SMT”) to mount the package 100 using solder. Mold compound 123 forms a body for the semiconductor device package 100. In an example, a thermosetting epoxy resin mold compound is used to form a solid body for the package 100.

FIG. 2B illustrates, in a cross-sectional view, the package 100 of FIG. 2A. In FIG. 2B, a semiconductor die 105 (see FIG. 1B, for example) is shown mounted to a leadframe 111 that has terminals 144 that are formed from leads partially exposed from the mold compound 123. The semiconductor die 105 is mounted to a die pad 142 that is part of the leadframe 111 by a die attach film 108. Wire bonds 158 form electrical connections between bond pads 102 on the device side surface of the semiconductor die 105 and the leads of the leadframe 111. The bond pads 102 are exposed from a passivation layer 156 which can be a polyimide, or other dielectric material. The mold compound 123 covers the semiconductor die 105, the wire bonds 158, the passivation layer 156, and portions of the leadframe 111. In this illustrated example a board side surface of the die pad 142 is exposed from the mold compound 123 to form a thermal pad that can be used to dissipate thermal energy from the semiconductor die 105 to a thermal pad on the module or circuit board, to assist in transferring heat from the semiconductor die 105 during operation.

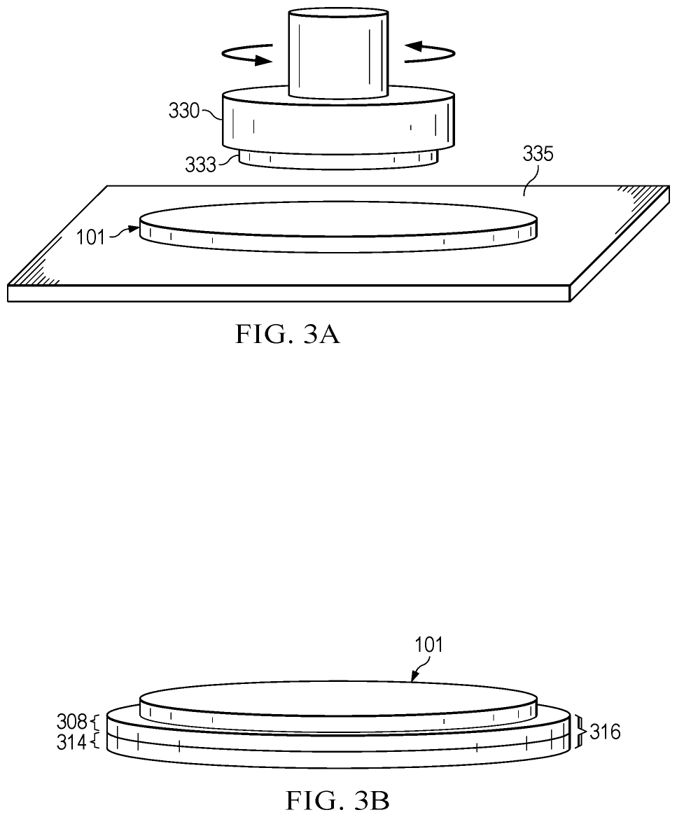

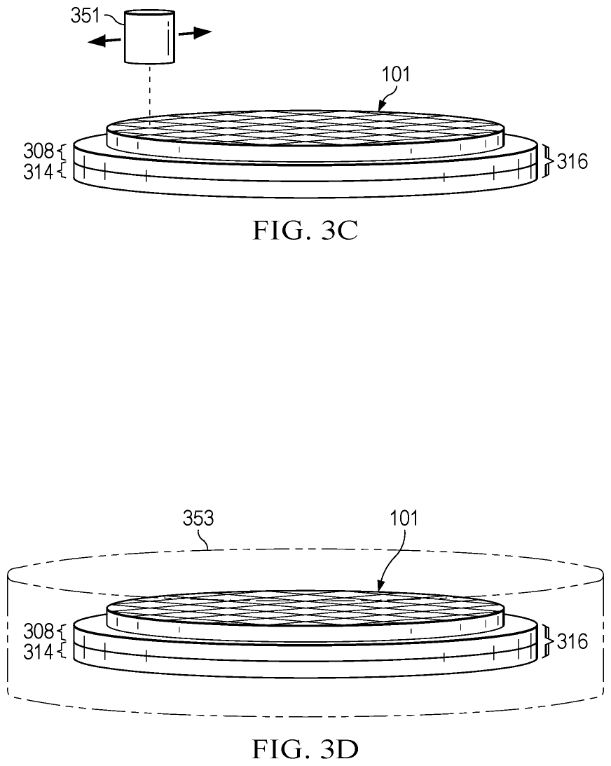

FIGS. 3A-3D illustrate, in a series of steps, selected portions of an example plasma dicing process. In FIG. 3A, semiconductor wafer 101 is shown in a backgrinding process. A backgrinding support tape or film 335 is shown supporting the semiconductor wafer 101 on the device side surface. The backgrinding tape or film 335 is a removable adhesive that can support the semiconductor wafer 101 and may be provided in a frame for support. The backgrinding tape 335 can be removed after processing by UV or photo release, by mechanical peeling, or by use of a chemical release agent, depending on the type of backgrinding tape used. As shown in FIG. 3A, a chemical mechanical polishing (“CMP”) tool includes a head 330 that mounts a polishing pad 333 which can carry an abrasive coating. The semiconductor wafer 101 is polished using either a wet or dry polishing process to thin the semiconductor wafer 101 for further processing. Thinning the semiconductor wafer 101 (and also the semiconductor dies on the semiconductor wafer) increases electrical performance of the semiconductor dies and can aid in enabling effective plasma dicing of the semiconductor wafer by reducing the material thickness. The rate of plasma dicing can also be increased by thinning the wafer, increasing throughput. In an example a semiconductor wafer thickness of approximately 100 microns after backgrinding was used.

At FIG. 3B, the semiconductor wafer 101 is shown mounted on a dicing die attach film 316. Dicing die attach film 316 is a two-layer film that has a die attach film 308 contacting the backside of the semiconductor wafer 101, and a removable dicing film 314 that supports the semiconductor wafer 101 and the die attach film 308. By laminating the two films 308, 314 together to form dicing die attach film 316 before application to the semiconductor wafer 101, the wafer processing can be simplified (when compared to separate mounting of the die attach film to the wafer, and then mounting the dicing film to the die attach film.) However, in an alternative approach, separate films 308, 314 can be used and separately applied to the backside of the semiconductor wafer 101.

FIG. 3C illustrates an optional step with a laser 351 traversing the device side surface of the semiconductor wafer 101, which is again shown mounted to die attach film 308, which is itself mounted on dicing film 314 to form dicing die attach film 316. The laser 351 can be used to groove the scribe lanes (see for example scribe lanes 103, 104 in FIG. 1A) and remove any metal layers in the scribe lanes to improve the subsequent plasma dicing processes. However, for semiconductor wafers without substantial metal in the scribe lanes, this laser grooving step may not be needed and can be omitted.

At FIG. 3D, the semiconductor wafer 101 is shown placed in a plasma process chamber 353. The semiconductor wafer 101 is mounted to the die attach film 308 and the die attach film 308 is mounted to the dicing tape 314, which are laminated together to form dicing die attach film 316. The plasma dicing process is an etch process which etches the semiconductor wafer 101 in the scribe lanes (see, for example, scribe lanes 103, 104 in FIG. 1A). After the semiconductor wafer 101 is etched through in the plasma chamber 353, additional processing is used to singulate the semiconductor dies from the semiconductor wafer 101 as is described in further detail below.

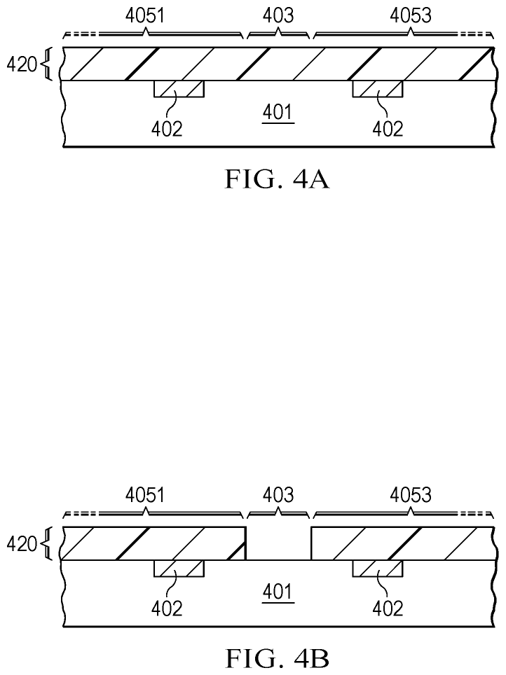

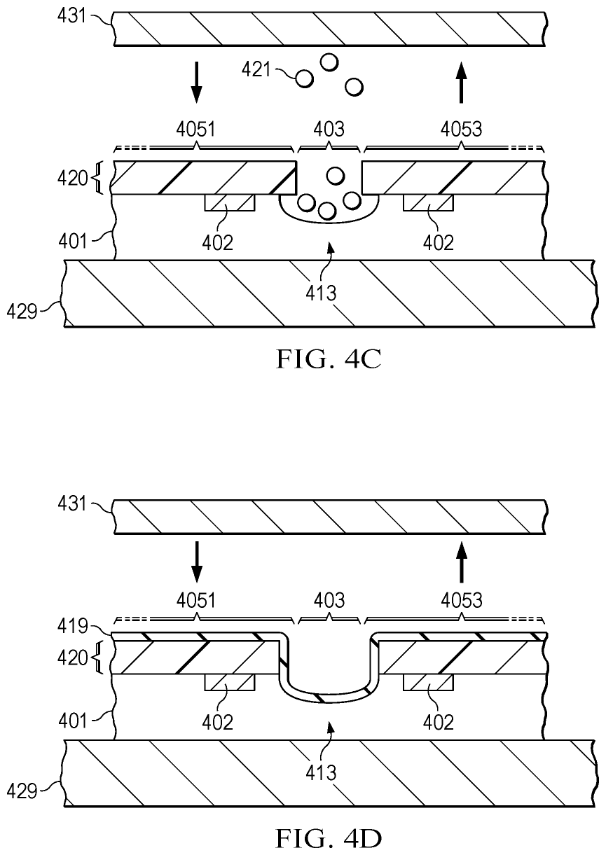

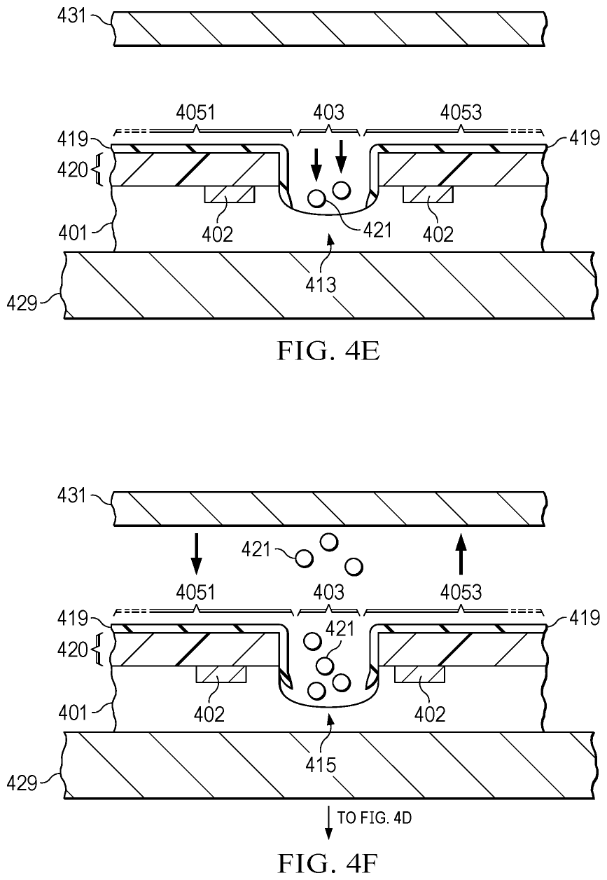

FIGS. 4A-4F show, in a series of cross-sectional views, a plasma dicing process that is useful with the arrangements, in additional detail. The plasma dicing step is performed in a plasma processing chamber (see 353 in FIG. 3D), which uses ionization to form a plasma from gaseous compounds introduced into the chamber that can be ionized. The ions are accelerated towards the surface of the semiconductor wafer and remove the semiconductor material in exposed areas. By varying the gaseous compounds in the chamber, material deposition and semiconductor etch can both be performed in the plasma chamber without removing the semiconductor wafer from the plasma chamber. Plasma chambers are used for various process steps in semiconductor manufacture including plasma vapor deposition (“PVD”) and semiconductor etch, including through-hole etch and via etch.

In FIG. 4A, a semiconductor wafer 401, similar to wafer 101 in FIG. 1A, is shown in part with bond pads 402 on the device side surface of example semiconductor dies 4051, 4053 spaced by a scribe lane 403. A mask 420 is shown formed over a device side surface of the semiconductor wafer 401. The mask 420 can be applied in a spin coating process for photoresist masks, for example.

In FIG. 4B, in another cross-sectional view, the elements of FIG. 4A are shown after photolithographic processing is used to pattern mask 420 to form openings exposing the scribe lanes such as 403 between semiconductor dies such as 4051, 4053. Hundreds or even thousands of semiconductor dies can be formed on a single semiconductor wafer simultaneously, reducing per unit costs and increasing throughput. The semiconductor dies 4051, 4053 will typically be identical units.

At FIG. 4C the plasma dicing process begins with semiconductor wafer 401 shown in a first plasma etching step. Semiconductor wafer 401 is placed on a wafer support 429 in a plasma process chamber. The plasma process chamber includes a processing head 431 that distributes processing gasses. Mask 420 is used to protect the semiconductor dies 4051, 4053 while a plasma etch uses ions to etch into the semiconductor wafer 401 from the device side surface in the scribe lane 403. The plasma etch process can use fluorine process gasses. In an example for silicon semiconductor etching a fluorine gas such as SF₆ (sulphur hexafluoride) can be used. To create the ions 421, the process gas is energized by an electric field in the plasma chamber to form a plasma (for example a radio-frequency signal can be applied to the plasma process head), and charge is applied between the head 431 and wafer support 429 to accelerate the ions 421 towards and cause the ions to strike the semiconductor wafer 401 and etch into the semiconductor wafer in the opening in the mask 420 exposing scribe lane 403. A trench 413 is formed in the first etch cycle shown in FIG. 4C. As can be seen by the shape of trench 413, the first semiconductor etch is somewhat isotropic, that is the etch affects the semiconductor wafer in several directions, etching into the semiconductor wafer in scribe lane 403 and etching somewhat beneath the mask 420.

At FIGS. 4D-4F, a Bosch process for recursively etching the semiconductor wafer is shown. After the initial etch of FIG. 4C is complete, the semiconductor wafer 401 is repeatedly etched, and a protective layer of material is deposited between etch cycles. The Bosch process produces highly anisotropic etch patterns so that a vertical trench with more or less straight sidewalls can be formed. At FIG. 4D, the plasma process deposits a protective layer 419 on the sidewalls and bottom of the trench 413 formed in FIG. 4C. In one example process, the fluorine gas used for etching is now switched to a fluorine gas that deposits material, in an example carbon tetrafluoride (CF₄) is used. A fluorocarbon layer is deposited as the layer 419 in FIG. 4D that covers the sidewalls and the bottom of trench 413.

FIG. 4E illustrates in another cross section the elements of FIG. 4D, now an additional etch is performed again using SF₆ in an example etch process. In this etch, an anisotropic etch is performed by charging both the process head 431 and the wafer support 429 to accelerate the ions 421 towards the bottom of the trench 413. The etch removes the fluorocarbon layer 419 from the bottom of the trench 413 to set up an additional trench etch cycle in a subsequent step.

FIG. 4F illustrates, in a further cross-sectional view of the plasma process chamber, the next etch in the Bosch cycle. The plasma process chamber now uses the SF₆ gas to perform an isotropic etch to extend the trench to form a deeper trench 415, and the etch opens the bottom and lower sidewalls of the trench. (This etch is similar to the isotropic etch of FIG. 4C.)

As shown in FIG. 4F, the process is recursive, after the etch of FIG. 4F, the process returns to the step shown in FIG. 4D, where the protective layer 419 is again deposited to keep the overall etch process vertical. As a result of the repeated etch and deposition steps, the sidewalls of the trench in the scribe lane 403 may have “scalloped” shapes when observed in a cross section. Further, in one approach, the passivation layer 419 can be left on the sidewalls of the trench 415, which will eventually form the vertical sides of semiconductor dies 4051, 4053. The scalloped sides can be cleaned to remove the fluorocarbon protective layer, or in another approach, the sides can retain the fluorocarbon protective layer. The recursive etch and deposit process of FIGS. 4D-FIG. 4F will be repeated until the trench 415 extends through the semiconductor wafer 401.

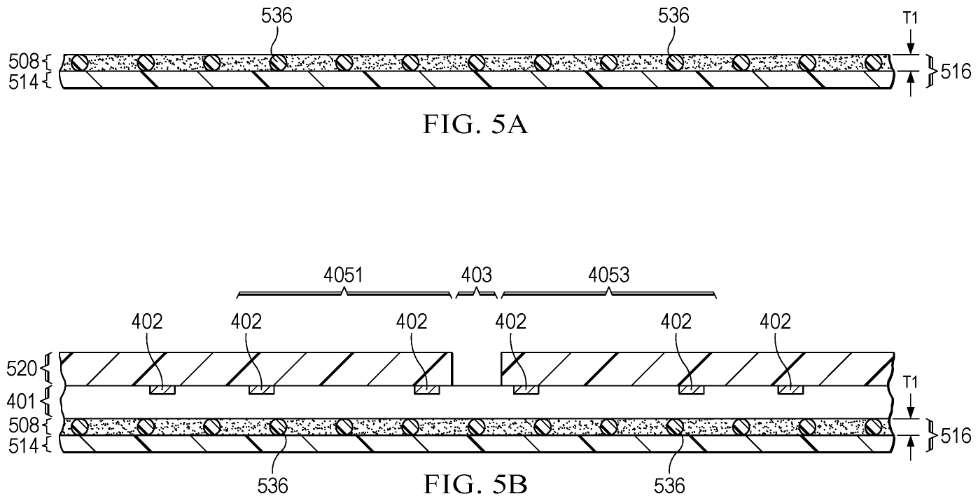

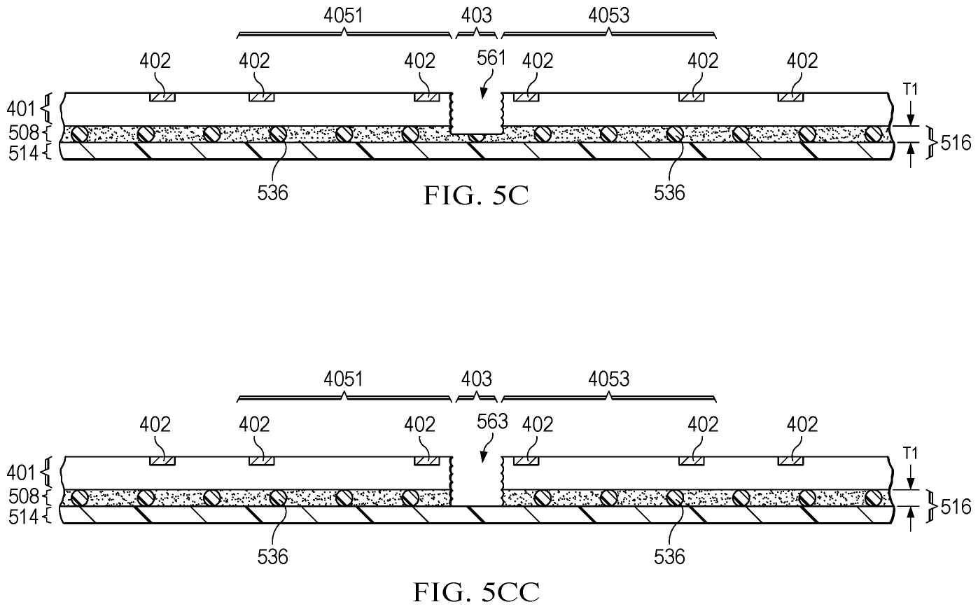

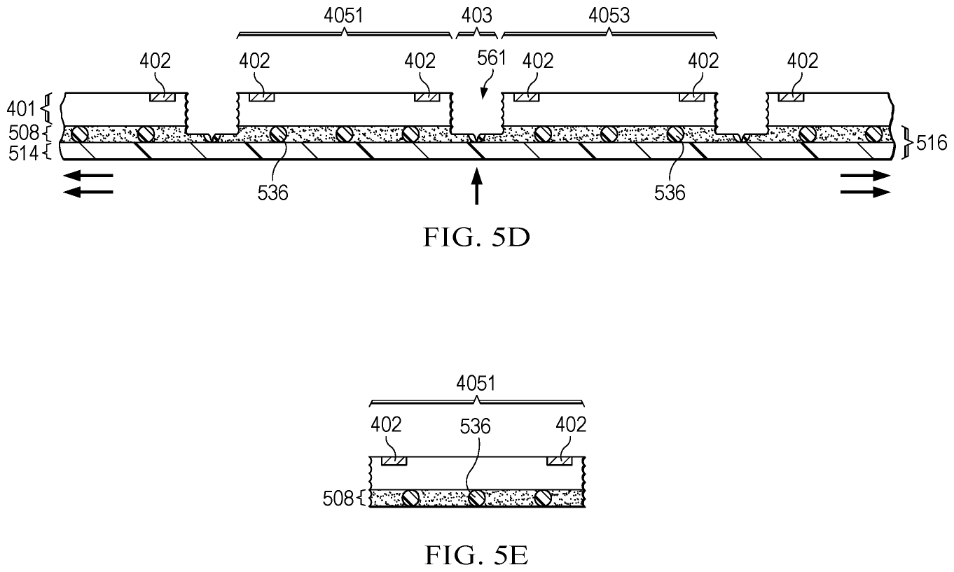

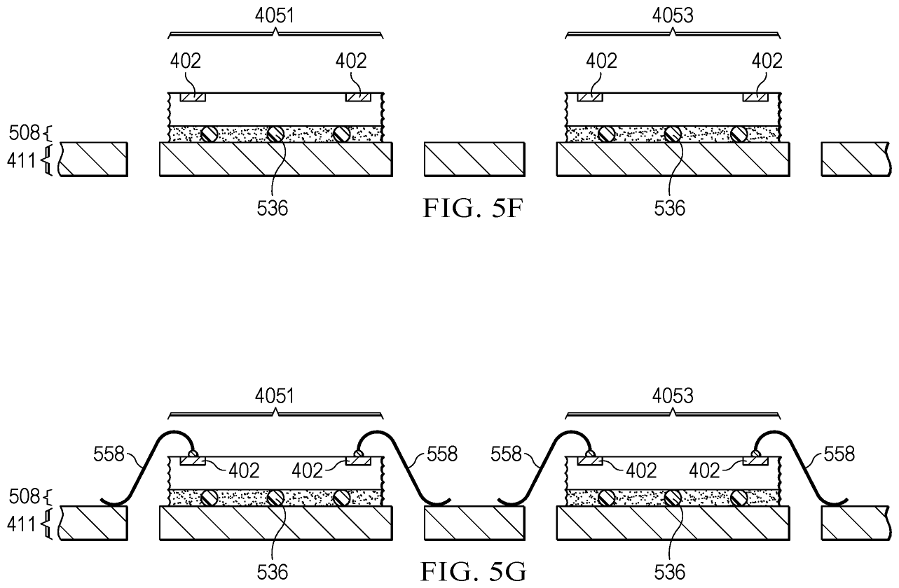

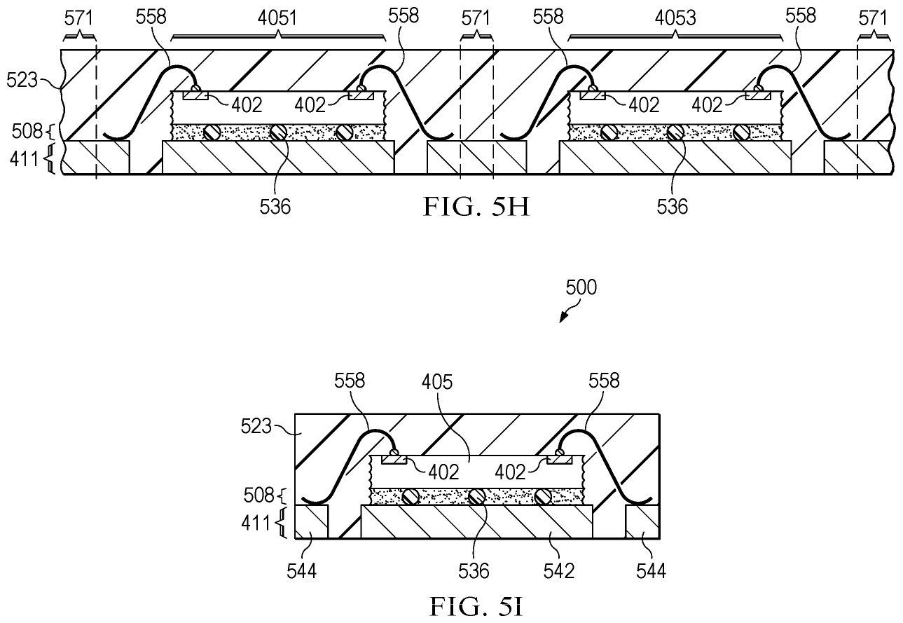

FIGS. 5A-5K illustrate, in another series of cross-sectional views, a method of using the plasma dicing steps described above with a dicing die attach film of the arrangements to form a packaged semiconductor device.

In FIG. 5A, in a cross-sectional view, a die attach film 508, and a dicing tape 514, are shown laminated together to form a dicing die attach film 516. The die attach film 508 includes particles 536 formed of polymers or of particles having a polymer coating. The particles 536 have diameters between 5-10 microns in one example, and the die attach film 508 has a thickness labeled “T1” in FIG. 5A of about 10 microns in an example. The polymer particles can have diameters ranging from about 5 to about 50 microns, with corresponding die attach film thicknesses. Use of a die attach film at the 10-micron thickness assists in making sure that the semiconductor dies and die attach film completely separate after plasma dicing. Note that although the particles 536 are shown with more or less uniform spacing for simplicity of illustration in FIG. 5A, and in the following figures, however in the die attach film the spacing between the polymer particles 536 will be random.

FIG. 5B illustrates the semiconductor wafer 401 with the dicing die attach film 516 mounted on the backside. The device side surface of the semiconductor wafer 401 includes dies 4051, 4053 with bond pads 402 on the device side surface, the semiconductor dies 4051, 4053 are spaced by a scribe lane 403.

FIG. 5C illustrates the elements of FIG. 5B after additional processing. In FIG. 5C, the semiconductor wafer 401 is shown following the plasma dicing process of FIGS. 4B-4F, where the plasma dicing process etches a trench in the scribe lane 403 through the semiconductor wafer 401 to separate the semiconductor dies 4051 and 4053. The trench 561 in the scribe lane 403 can extend partially into the surface of the die attach film 508, as shown in FIG. 5C. The plasma etch process can etch the die attach film 508 with the polymer particles. This aspect of the use of the novel die attach film 508 in the arrangements is in sharp contrast to and advantageous over the use of previous die attach films with silica or alumina particles, which are resistant to plasma etch processes, making plasma etch of those conventional die attach films very inefficient or impossible.

In FIG. 5CC, an alternative arrangement is shown. In the example of FIG. 5CC, the plasma dicing process (see FIGS. 4B-4F) is used to etch through both the semiconductor wafer 401, separating semiconductor dies 4051, 4053 by forming trench 563 in the scribe lane 403, and the plasma process also continues and etches through the die attach film 508. By using the plasma dicing process to cut through the die attach film 508, subsequent steps to tear apart the die attach film 508 are not needed. As described below, these steps require stretching the dicing tape 514 to tear the die attach film 508.

FIG. 5D illustrates, in another cross-sectional view, the die attach film 508 of FIG. 5C being torn to separate the semiconductor dies 4051, 4053 apart using the dicing tape 514 in an expansion step. Depending on the type of dicing tape used, the expansion step can be a cold expansion, or can be at an elevated temperature. While the dicing tape 514 supports the semiconductor dies 4051, 4053 and the die attach film 508, the dicing tape 514 is stretched, since this dicing tape has elastic properties. In an example process, the center of the dicing tape 514 is raised while the outer edges are clamped in place to stretch the dicing tape 514 in multiple directions. The die attach film 508 shears apart in the trench 561, since the die attach film 508 is less elastic than the dicing tape 514. In this manner the semiconductor dies and the corresponding portions of the die attach film 508 on the backside surface are separated from one another and are ready for a die pick and place operation. A pick and place tool can then be used to remove the individual semiconductor dies and the corresponding die attach film 508 from the dicing tape 514. The dicing tape 514 can be a UV release, photo release or other type of release tape, or can be a peelable tape.

FIG. 5E illustrates, in a further cross-sectional view, the separated semiconductor die 4051, with bond pads 402 on a device side surface, and with the die attach film 508 on an opposite backside surface, ready for use. As shown in FIG. 5E, the vertical sides of the semiconductor die 4051 have scalloped shapes due to the plasma dicing process used to dice the semiconductor wafer.

FIGS. 5F-5I illustrate, in additional cross-sectional views, the remaining steps needed to form a packaged semiconductor device using the semiconductor dies of the arrangements. In FIG. 5F, the semiconductor dies 4051, 4053 are shown mounted to die pads of a leadframe 411. The leadframe 411 can be provided in a strip, array or matrix of unit leadframes for forming packaged devices. Tens, hundreds or more semiconductor dies can be processed simultaneously to increase throughput and reduce unit costs. The example semiconductor dies 4051 and 4053 are mounted to the die pads of the leadframe 411 by the die attach film 508 which includes the polymer particles 536. The polymer particles can be polystyrene, polymethyl methacrylate (PMMA), or polytetrafluoroethylene (PTFE). Polymer particles useful in the arrangements can vary in size from 5-50 microns, with a 10-micron diameter in an example with a corresponding 10-micron thickness for the die attach film 508. Other thicknesses can be used, the die attach film thickness can be chosen to ensure the complete separation of the devices. In addition to the polymer particles, the die attach film 508 includes additional materials, including for example resins and/or epoxies, curing agents, and additional filler particles that are smaller than the polymer particles may be present, and additives such as coupling agents. Catalyst chemicals such as imidazole can be included in the die attach film 508.

The semiconductor dies 4051, 4053 can be positioned on the leadframe 411 using a pick and place tool that removes the semiconductor dies and the corresponding die attach film from the dicing tape (see FIG. 5D, or FIG. 5CC, for example, and dicing tape 514). After die mount using the die attach film, which can be performed at an elevated temperature of about 100-150 degrees C., a cure of the die attach film 508 can be performed by placing the leadframe strips or arrays with the semiconductor dies attached in an oven. An example process performs a die attach film post-mount cure at 180 degrees C. for about an hour.

FIG. 5G illustrates, in a further cross-sectional view, the elements of FIG. 5F after additional processing. In FIG. 5G, wire bonds 558 are formed coupling bond pads 402 on the semiconductor dies 4051, 4053 to leads on the leadframe 411. The wire bonds 558 can be formed using bond wires of copper, palladium coated copper, gold, aluminum or silver. Recently copper bond wires and PCC bond wires are increasingly used. When copper bond wires or PCC bond wires are used in a wire bonding process, the mechanical pressure applied to the bond pads during bonding is necessarily increased (compared to other bond wire types), as the copper bond wire is harder than gold or silver bond wire. Particularly for small dies of less than 0.1 millimeter on a side, die tilt during bonding can result. By using the die attach film of the arrangements including the polymer particles, the die tilt can be reduced or eliminated because the polymer particles are hard and resist die tilt during wire bonding, providing improved mechanical support to the semiconductor dies during bonding (when compared to prior die attach films).

In an example wire bonding process that can be used with the arrangements, a wire bonding tool has a bond wire supply that allows the free end of a bond wire to extend through a central opening in a capillary. The capillary is of a hard material such as a ceramic that can be used to apply mechanical pressure to the bond wire. The free end of the bond wire is melted using an electronic arc or flame to form a molten ball. The capillary is used to press the molten ball onto a bond pad using mechanical force, ultrasonic vibration of the capillary, and thermal energy to form a bond between the ball and the bond pad. This thermosonic bonding process can be performed at an elevated temperature. To prevent rapid oxidation of the copper bond pads and the bond wire in a copper or palladium coated copper bond wire process, an anoxic environment may be created in the wire bonding tool, for example by using an inert gas in a process chamber during the wire bonding process.

After the ball bond is formed on a bond pad on the semiconductor die, the capillary moves away from the ball bond while allowing the bond wire to extend from the capillary. Using clamps to control the bond wire, the bond wire can be shaped in an arc above the outer edge of the semiconductor die and extend over a lead of the leadframe. The capillary then uses mechanical pressure, ultrasonic vibration and thermal energy to form a “stitch” bond on the lead. The capillary then moves a short distance away from the stitch bond and the bond wire is cut or broken to form a new free end extending from the opening in the capillary. The wire bonding cycle is recursive, is highly automated and can be repeated rapidly to form the wire bonds needed for each semiconductor die, with many wire bonds formed per second to enable rapid throughput.

FIG. 5H illustrates the elements of FIG. 5G after a molding process. Mold compound 523 is formed over the semiconductor dies 4051, 4053, portions of the leadframe 411, the die attach film 508, and the wire bonds 558. In an example process, the mold compound 523 extends over the leadframe 411 and covers both semiconductor dies 4051, 4053 and a saw street 571 between the devices. In an alternative process, the mold compound 523 can be shaped around each semiconductor die 4051, 4053.

In an example molding process that can be used to form the mold compound 523, a transfer molding process can be used with a thermoset epoxy resin electronic mold compound (“EMC”). The mold compound can be provided into a mold tool as a solid or as a powder at room temperature. The solid mold compound is heated and transitions to a liquid state. The liquid mold compound is forced through runners into a mold chase where the leadframe 411 and the semiconductor dies 4051, 4053 are placed. After filling the mold chase and surrounding the elements, the mold compound is cured to form a solid body. Alternatives to the thermoset epoxy resin include resins, epoxies, and room temperature processes. Fillers can be used to increase the thermal transfer properties of the mold compound.

FIG. 5I illustrates, in another cross-sectional view, a semiconductor device package 500 formed using the arrangements. To transition from FIG. 5H to FIG. 5I, a sawing operation is performed along saw streets between the unit semiconductor dies (see 4051, 4053 in FIG. 5H, and saw street 571) to separate the packaged semiconductor devices 500 one from another. The packaged semiconductor device 500 is similar to packaged semiconductor device 100 in FIG. 2B, and is a QFN package. The packaged semiconductor device 500 includes semiconductor die 405, which can be one of 4051, 4053 from FIG. 5G. and die attach film 508, including the polymer particles 536. In another advantage of the arrangements, use of the polymer particles 536 can reduce or eliminate another current leakage path that conventional die attach films sometimes exhibit. When a conventional die attach film with alumina (Al₂O₃) or silica (SiO₂) particles is used to mount a semiconductor die to a die pad on a copper leadframe (see die pad 542 in FIG. 5I), electromigration has been observed where copper or silver plating from the die pad surface migrates on the surface of the particles and can contact the backside of the semiconductor die mounted to the die attach film, creating a current leakage path. In contrast, the novel die attach film 508 of the arrangements includes polymer particles 536, which do not exhibit the electromigration problems of prior die attach films, eliminating this possible current leakage path from the packaged devices formed using the arrangements.

Use of the novel dicing die attach film with the polymer particles in forming the arrangements enables efficient use of plasma wafer dicing, while ensuring complete device separation during die singulation. Plasma dicing as used in the arrangements is particularly advantageous because the minimum scribe lane spacing between semiconductor dies can be greatly reduced (when compared to either mechanical saw dicing or laser wafer dicing), increasing the device yield. The plasma dicing process also has throughput advantages because instead of making multiple single cut passes along the scribe lanes, as is done for both mechanical sawing and laser wafer dicing, the plasma dicing process can etch through the semiconductor wafer material in all of the scribe lanes simultaneously, increasing throughput. The semiconductor devices diced using plasma dicing are not subjected to the stress of a mechanical saw, or to the formation of heat affected zones needed for laser dicing. The plasma dicing process is particularly significant for small dies of less than 0.25 millimeters on a side, and even down to 0.1 millimeters on a side, because the smaller scribe lane width permitted in plasma dicing allows for substantially more semiconductor dies to be formed on a semiconductor wafer, greatly reducing unit costs. In an example process, the plasma dicing scribe lane width can be as low as 5-10 microns. In addition, the use of thinner semiconductor wafers is increasing, which reduces the wafer thickness needed to be etched through in the plasma process, further increasing plasma dicing throughput. Semiconductor wafers diced using plasma dicing have also been shown to be stronger than dies from similar semiconductor wafers diced by other methods, due to the reduced mechanical stress on the semiconductor dies during plasma dicing.

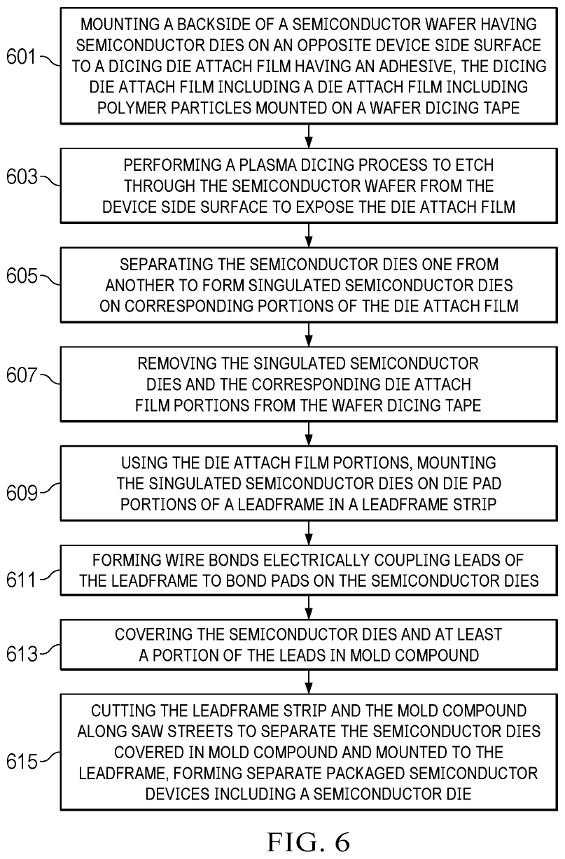

FIG. 6 illustrates, in a flow diagram, a method for forming a semiconductor device package of an arrangement. The method begins at step 601, by mounting a backside of a semiconductor wafer having semiconductor dies on an opposite device side surface to a dicing die attach film having an adhesive, the dicing die attach film including a die attach film including polymer particles mounted on a wafer dicing tape. (See, for example, FIG. 5B, with die attach film 508 with polymer particles 536 attached to wafer dicing tape 514, forming dicing die attach film 516).

At step 603, the method continues by performing a plasma dicing process to etch through the semiconductor wafer from the device side surface to expose the die attach film. (See, for example, trench 561 in the semiconductor wafer 401 in FIG. 5C, after a plasma dicing process, exposing die attach film 508). The die attach film with the polymer particles is fully compatible with plasma etching, in contrast to certain die attach films used previously, such as silica filled die attach film.

At step 605, the method separates the semiconductor dies one from another to form singulated semiconductor dies on corresponding portions of the die attach film. (See, for example, FIG. 5CC, where the plasma process continues through the die attach film to form singulated semiconductor dies 4051, 4053. See also, for example, FIG. 5D, where an expansion process tears the die attach film 508 between semiconductor dies 4051, 4053, in an alternative approach).

At step 607, the method continues by removing the singulated semiconductor dies and the corresponding die attach film portions from the wafer dicing tape. (See, for example, semiconductor die 4051 in FIG. 5E, mounted on die attach film 509.)

At step 609, the method continues by using the die attach film portions, mounting the singulated semiconductor dies on die pad portions of a leadframe in a leadframe strip. (See, for example, FIG. 5F, with semiconductor dies 4051, 4053 mounted on leadframe 411).

At step 611, wire bonds are formed electrically coupling leads of the leadframe to bond pads on the semiconductor dies. (See, for example, FIG. 5G, where semiconductor dies 4051, 4053 are shown with wire bonds 558 formed to couple the bond pads 402 to the leads of the leadframe 411). As described above, the polymer particles in the novel die attach film provide increased mechanical support to the semiconductor dies during wire bonding, providing advantages over prior approach die attach films.

At step 613, the method continues by covering the semiconductor dies and at least a portion of the leads in mold compound. (See mold compound 523 in FIG. 5H).

At step 615, the method completes by cutting the leadframe strip and the mold compound along saw streets to separate the semiconductor dies covered in mold compound and mounted to the leadframe, forming separate semiconductor device packages each including a semiconductor die. (See, for example, FIG. 5I, package 500 includes semiconductor die 405).

Modifications and variations are contemplated and can be made in the described arrangements, and other alternative arrangements are possible that are within the scope of the claims.

What is claimed is:

1. A method for forming a packaged semiconductor device, comprising:
mounting a backside of a semiconductor wafer having semiconductor dies on an opposite device side surface to a dicing die attach film having an adhesive, the dicing die attach film comprising a die attach film including polymer particles mounted on a wafer dicing tape;
performing a plasma dicing process to etch through the semiconductor wafer from the device side surface to expose the die attach film in scribe lanes between the semiconductor dies;
separating the semiconductor dies one from another to form separated semiconductor dies attached to corresponding portions of the die attach film;
removing the semiconductor dies and the corresponding portions of the die attach film from the wafer dicing tape;
using the die attach film, mounting the semiconductor dies on die pad portions of leadframes in a leadframe strip;
forming wire bonds electrically coupling leads of the leadframes to bond pads on the semiconductor dies;
covering the semiconductor dies and at least a portion of the leads of the leadframes in mold compound; and
cutting the leadframe strip and the mold compound along saw streets between the leadframes to separate the leadframes from the leadframe strip, forming separate semiconductor device packages each including a semiconductor die.

2. The method of claim 1, wherein separating the semiconductor dies one from another to form separated semiconductor dies attached to corresponding portions of the die attach film further comprises:
stretching the wafer dicing tape to tear the die attach film in the scribe lanes to form the separated semiconductor dies.

3. The method of claim 1, wherein separating the semiconductor dies one from another to form separated semiconductor dies attached to corresponding portions of the die attach film further comprises:
during the plasma dicing process, after etching through the semiconductor wafer in the scribe lanes, continuing to etch through the die attach film.

4. The method of claim 1, wherein mounting a backside of a semiconductor wafer having semiconductor dies on an opposite device side surface to a dicing die attach film having an adhesive, the dicing die attach film comprising a die attach film including polymer particles mounted on a wafer dicing tape further comprises: mounting the backside of the semiconductor wafer on the die attach film including polymer particles having a diameter between 5 microns and 50 microns.

5. The method of claim 4, wherein the polymer particles are of polystyrene, polymethyl methacrylate (PMMA), or polytetrafluoroethylene (PTFE).

6. The method of claim 1, wherein the die attach film has a thickness of about 10 microns, and the polymer particles have a diameter of about 10 microns.

7. The method of claim 1, wherein performing a plasma dicing process to etch through the semiconductor wafer from the device side surface to expose the die attach film in scribe lanes between the semiconductor dies further comprises:
forming a mask over the semiconductor wafer;
patterning the mask to expose the semiconductor wafer in the scribe lanes between the semiconductor dies;
using a first isotropic plasma etch process, performing an etch into the semiconductor wafer in the scribe lanes to form trenches;
using a plasma deposition process, forming a passivation layer over a bottom of the trenches and over sidewalls of the trenches;
using an anisotropic plasma etch process, performing an etch to remove the passivation layer from the bottom of the trenches;
using a second isotropic plasma etch process, performing an etch into the semiconductor wafer in the scribe lanes to deepen the trenches; and
repeating the plasma deposition process, the anisotropic plasma etch process, and the second isotropic plasma etch process, extending the trenches until the die attach film beneath the semiconductor wafer is exposed in the trenches.

8. The method of claim 1, and further comprising:
prior to mounting a backside of a semiconductor wafer having semiconductor dies on an opposite device side surface to a dicing die attach film having an adhesive, the dicing die attach film comprising a die attach film including polymer particles mounted on a wafer dicing tape, mounting the device side surface of the semiconductor wafer to a removable backgrinding tape, and grinding the backside surface of the semiconductor wafer to thin the semiconductor wafer.

9. The method of claim 8, wherein grinding the backside surface of the semiconductor wafer to thin the semiconductor wafer further comprises grinding using chemical mechanical polishing.

10. The method of claim 1, wherein forming wire bonds electrically coupling leads of the leadframes to bond pads on the semiconductor dies further comprises using bond wire of copper, palladium coated copper, gold, silver or aluminum.

11. The method of claim 1, wherein forming wire bonds electrically coupling leads of the leadframes to bond pads on the semiconductor dies further comprises using bond wire comprising copper.

12. The method of claim 1, wherein the semiconductor dies have an area less than or equal to 0.1 millimeter by 0.1 millimeter.

13. The method of claim 1, wherein the semiconductor dies have an area less than or equal to 0.25 millimeters by 0.25 millimeters.

14. The method of claim 1, wherein the leadframe strip comprises copper.

15. The method of claim 1, wherein the die pad portions of the leadframes comprise copper with a silver plating.

16. A method of forming a semiconductor device package, comprising:
mounting a backside of a semiconductor wafer having semiconductor dies on an opposite device side surface to a dicing die attach film having an adhesive, the dicing die attach film comprising a die attach film including polymer particles having a diameter of between 5 and 10 microns mounted on a wafer dicing tape;
in a plasma processing chamber, performing a plasma dicing process to etch through the semiconductor wafer from the device side surface in scribe lanes between the semiconductor dies to expose the die attach film;
separating the semiconductor dies one from another to form separated semiconductor dies attached to corresponding portions of the die attach film by stretching the wafer dicing tape to tear the die attach film apart in the scribe lanes, forming corresponding portions of the die attach film;
removing the separated semiconductor dies and the corresponding die attach film portions from the dicing tape;
using the corresponding die attach film portions, mounting the semiconductor dies on die pad portions of leadframes in a leadframe strip;
forming wire bonds electrically coupling leads of the leadframes to bond pads on the semiconductor dies;
covering the semiconductor dies and at least a portion of the leads in mold compound; and
cutting the leadframe strip and the mold compound along saw streets between the leadframes, forming semiconductor device packages each including a semiconductor die.

17. The method of claim 16, wherein forming wire bonds electrically coupling leads of the leadframes to bond pads on the semiconductor dies further comprises forming wire bonds of copper or palladium coated copper bond wire.

18. The method of claim 16, wherein forming semiconductor device packages each including a semiconductor die comprises forming quad flat no lead (QFN) semiconductor device packages.

19. The method of claim 16, wherein performing a plasma dicing process to etch through the semiconductor wafer from the device side surface in scribe lanes between the semiconductor dies to expose the die attach film further comprises recursively etching the semiconductor wafer in the scribe lanes and recursively forming passivation material in the scribe lanes to form a trench with scalloped sidewalls extending through the semiconductor wafer.

20. A semiconductor device package, comprising:
a semiconductor die having a backside surface mounted to a die pad of a leadframe using a die attach film that comprises polymer particles, the leadframe having conductive leads spaced from the die pad;
wire bonds coupling bond pads on a device side surface of the semiconductor die that is opposite the backside surface to the leads of the leadframe; and
mold compound covering the semiconductor die, the wire bonds, and portions of the leads of the leadframe, with additional portions of the leads of the leadframe exposed from the mold compound to form terminals;
wherein the semiconductor die has vertical sides extending from the backside surface to the device side surface that have a scalloped pattern.

21. The semiconductor device package of claim 20, wherein the die attach film that comprises polymer particles comprises the polymer particles of polystyrene, polymethyl methacrylate (PMMA), or polytetrafluoroethylene (PTFE).

22. The semiconductor device package of claim 20, wherein the die attach film that comprises polymer particles comprises polymer particles having a diameter of between 5 and 50 microns.

23. The semiconductor device package of claim 20, wherein the die attach film that comprises polymer particles comprises polymer particles having a diameter of about 10 microns, and the die attach film has a thickness of at least 10 microns.
